(19) United States
(12) Patent Application Publication
(10) Pub. No.: US 2014/0174812 A1
(43) Pub. Date: Jun. 26, 2014

(54) Method and Apparatus for Far End Crosstalk Reduction in Single Ended Signaling

(71) Applicants: Raul Enriquez Shibayama, Zapopan (MX); Kai Xiao, University Place, WA (US); Nicte A. Zavala Castro, Guadalajara (MX); Mauro Lai, Tacoma, WA (US); Yanjie Zhu, Folsom, CA (US)

(72) Inventors: Raul Enriquez Shibayama, Zapopan (MX); Kai Xiao, University Place, WA (US); Nicte A. Zavala Castro, Guadalajara (MX); Mauro Lai, Tacoma, WA (US); Yanjie Zhu, Folsom, CA (US)

(21) Appl. No.: 13/725,650

(22) Filed: Dec. 21, 2012

(51) Int. Cl. H05K 9/00

(52) U.S. Cl. CPC H05K 9/00
USPC 174/350; 174/70 R; 427/97.1

(57) ABSTRACT

A method of reducing crosstalk. The method may include forming a first contact over a first vertical conductor. The method may include forming a second contact over a second vertical conductor. The method may include forming a third contact over a third vertical conductor. The method may include forming a capacitive coupler between the first contact, the second contact, and the third contact, wherein the capacitive coupler is to cancel crosstalk received at the second vertical conductor and third vertical conductor from the first vertical conductor.

### TECHNICAL FIELD

This disclosure relates generally to techniques for reducing far end crosstalk. Specifically, this disclosure relates to reducing far end crosstalk by introducing capacitive coupling of neighboring signal nets.

### BACKGROUND ART

Computing devices may include a motherboard such as a printed circuit board (PCB). The motherboard may hold various components of the computing device such as a central processing unit (CPU) and memory, and may provide connections for other peripheral components. The CPU may be coupled to the motherboard via a packaging technology such as a land grid array (LGA), a pin grid array (PGA), and the like. A LGA is packaging for integrated circuits that is notable for having the pins on a socket rather than an integrated circuit that may be present in other packaging, such as in a PGA. In many packaging technologies, crosstalk is generated within the packaging. Crosstalk creates distortion in signals communicated through the channels.

### BRIEF DESCRIPTION OF THE DRAWINGS

FIG. 1 is a block diagram showing a printed circuit board and a package.

FIG. 2 is a perspective view showing a portion of the package including a capacitive coupler between a first contact, a second contact, and a third contact.

FIG. 3 is a side view showing a portion of the package including the capacitive coupler between the first contact, the second contact, and the third contact.

FIG. 4 is a top view showing a portion of the package including the capacitive coupler between the first contact, the second contact, and the third contact.

FIG. 5 is a top view showing a portion of the package including the capacitive coupler between the first contact and the second contact, and the third contact.

FIG. 6 is a diagram showing the capacitive coupler including a relatively larger conductive plate.

FIG. 7 is a block diagram showing a method of manufacturing a printed circuit board to reduce crosstalk between contacts.

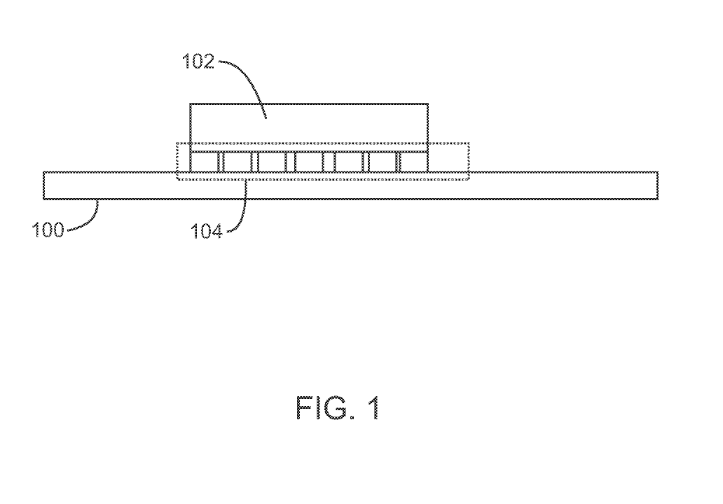

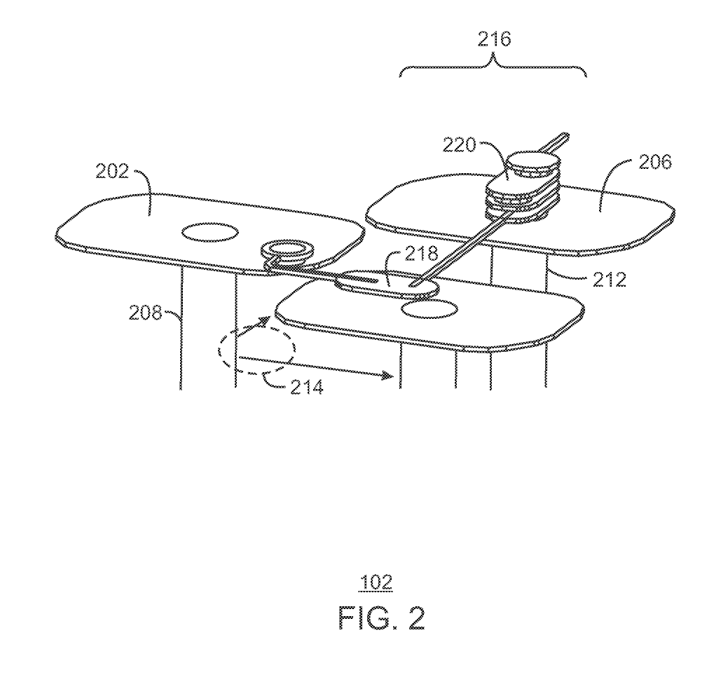

The same numbers are used throughout the disclosure and the figures to reference like components and features. Numbers in the 100 series refer to features originally found in FIG. 1; numbers in the 216 series refer to features originally found in FIG. 2; and so on.

### DESCRIPTION OF THE EMBODIMENTS

The present disclosure relates generally to techniques for reducing crosstalk between contacts. A package configured to couple inputs/outputs (I/O's) associated with electrical components to a printed circuit board (PCB) includes a first contact, a second contact, and a third contact. In embodiments, the contacts may include additional contacts, and is not limited to three contacts. Each of the contacts is coupled to a vertical conductor, such as a microvia, that communicatively couples the contacts to electrical components disposed at various layers in the package. The second contact and the third contact experience crosstalk generated at a first vertical conductor coupled to the first contact. The crosstalk generated at the first vertical conductor is inductive. The inductive crosstalk tends to create noise in signals nets associated with the second and third contacts, respectively. For example, the second contact can be associated with a signal net that can receive inductive crosstalk from the first vertical conductor. The inductive crosstalk is reduced by forming a capacitive coupler between the first and second contact and second and third contact respectively. The capacitive coupler introduces capacitive crosstalk configured to compensate for the inductive crosstalk, and thereby reduce or cancel the inductive crosstalk generated at the first vertical conductor.

FIG. 1 is a block diagram showing a printed circuit board 100 (PCB) and a package 102. The package 102 is a dielectric substrate configured to receive silicon die or other I/O's associated with electronic components to be electrically coupled into the PCB 100. The package 102 is communicatively coupled to the PCB 100 via conductive elements indicated by the dashed circle 104. The conductive elements 104 include any suitable object for communicating electrical signals, including signal nets, with the PCB 100. A “signal net,” as referred to herein, is a conductor, including a pair of conductors, such as a PCB trace, a via, a land grid array socket pin, ball grid array ball, pin grid array pin, and the like, configured to carry electrical signals. The package 102 is configured to receive one or more electrical components such as microchips, processors, memory devices, and logic circuits, among other circuit components. The package 102 includes structures for reducing crosstalk including capacitive couplers, contacts, and vertical conductors as explained below in reference to FIGS. 2-5.

FIG. 2 is a perspective view showing a portion of the package 102 including a first contact 202, a second contact 204, and a third contact 206. The package 102 is mounted on the surface of the PCB 100. The package 102 is configured to provide a coupling between the PCB and electrical components. The package 102 includes conductive elements including conductive pathways configured to couple internal components of the package 102 to each other. The conductive pathways may be configured to communicate single-ended signals. “Single-ended signals,” as referred to herein, is a circuitry structure wherein conductive pathways carry signals having a voltage and are grounded by reference planes within the package 102.

The first contact 202 is coupled to a first vertical conductor 208. The second contact 204 is coupled to a second vertical conductor 210. The third contact 206 is coupled to a third vertical conductor 212. The vertical conductors 208, 210, 212 couples the circuit components of the package 102 to signal lines of the PCB 100. The contacts 202, 204, 206 may configured in different shapes and sizes. A “vertical conductor,” as referred to herein, is a conductive element, such as a via, a socket, a pin, and the like. In some embodiments, vertical conductors 208, 210, 212 are disposed having a different orientation with respect to the term “vertical,” and is “horizontal,” “diagonal,” or among other orientations. The vertical conductor 212 can experience crosstalk that can create noise in a signal at a different vertical conductor. For example, crosstalk can be generated at the first vertical conductor 208 and received at the second vertical conductor 210 and the third vertical conductor 212, as indicated by the arrows of the dashed circle 214. In some embodiments, the crosstalk generated is based on the proximity of the first vertical conductor 208 to the either the second vertical conductor 210 or the third vertical conductor 212. The crosstalk generated at the first vertical conductor 208 is inductive crosstalk.

The package 102 can also include a capacitive coupler 216 disposed between the first contact 202, the second contact 204, and the third contact 206. The capacitive coupler 216 can be configured to reduce or cancel the inductive crosstalk generated at the first vertical conductor 208 and received at the second vertical conductor 210 and the third vertical conductor 212. The capacitive coupler 216 may include a conductive plate 218 disposed above the second contact 204. The capacitive coupler 216 can include another conductive plate 220 disposed above the third contact 206. As shown in FIG. 2, the conductive plate 220 is disposed at the bottom of an interconnect. In some embodiments, a dielectric material is disposed between the conductive plates 218, 220 and the second contact 204 and third contact 206, respectively. In other words, the conductive plates 218, 220 are capacitively connected to the contacts 204, 206. The introduction of a capacitance connection via the capacitive coupler 216 and conductive plates 218, 220 tends to reduce or cancel the inductive crosstalk generated at the first vertical conductor 208 and received at the second vertical conductor 210 and the third vertical conductor 212.

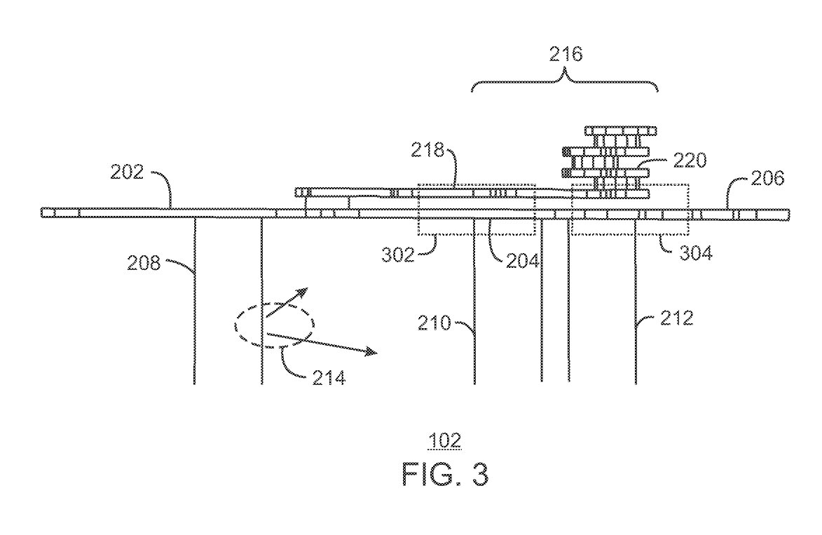

FIG. 3 is a side view showing a portion of the package 102 including the capacitive coupler 216 between the first contact 202, the second contact 204, and the third contact 206. The capacitive coupler 216 can include the conductive plate 218 disposed above the second contact 204 to form a parallel-plate capacitor, as indicated by the dashed line 302, with the second contact 204. The capacitive coupler 216 includes the conductive plate 220 disposed above the third contact 206 to form a parallel-plate capacitor, as indicated by the dashed line 304, with the third contact 206. In some embodiments, a dielectric material is included in between the conductive plate 302 and the second contact 204. As indicated by the dashed oval 214, inductive crosstalk is generated between the vertical conductors 208, 210, 212. As discussed above in reference to FIG. 2, the capacitive coupler 216 is configured to introduce capacitive crosstalk to reduce or cancel the inductive crosstalk generated between the vertical conductors 208, 210, 212.

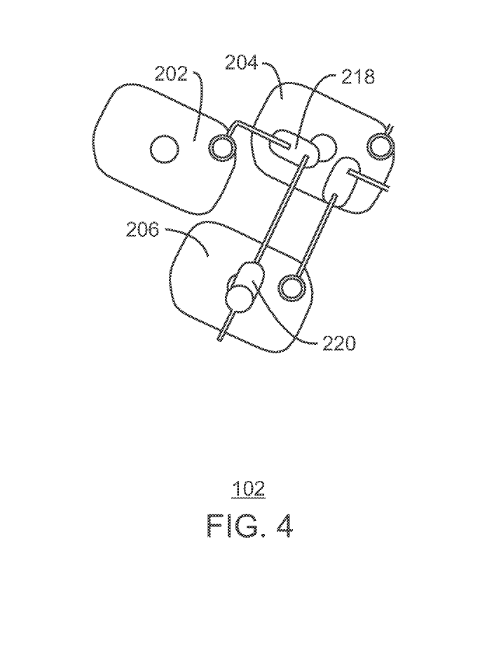

FIG. 4 is a top view showing a portion of the package 102 including the capacitive coupler 216 between the first contact 202, the second contact 204, and the third contact 206. In some embodiments, the capacitive coupler 216 is a sequential coupler as illustrated in FIG. 4. The first vertical conductor associated with the first contact 202 generates the inductive crosstalk. As shown in FIG. 4, the first contact 202 is coupled via the capacitive coupler 216 to the second contact 204, and from the second contact 204 to the third contact 206 in sequence. The capacitive coupler 216 is conductively coupled to the first contact 202, and capacitively coupled to each of the second and third contacts 204, 206, respectively.

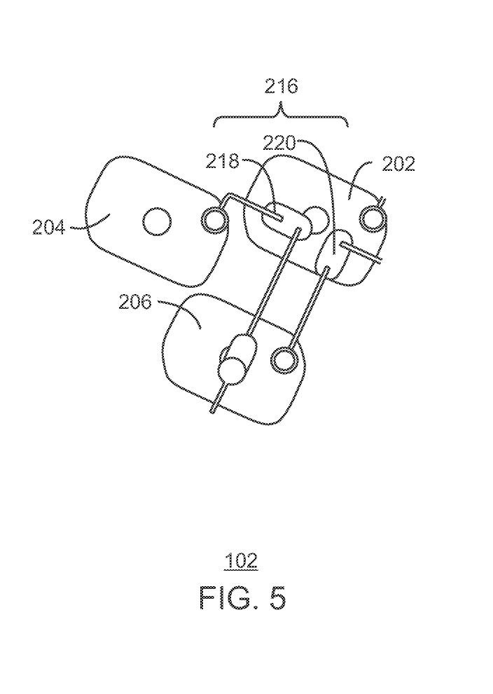

FIG. 5 is a top view showing a portion of the package 102 including the capacitive coupler 216 between the first contact 202, the second contact 204, and the third contact 206. In some embodiments, the capacitive coupler 216 is a parallel coupler as illustrated in FIG. 5. The second vertical conductor (not shown) and third vertical conductor (not shown) coupled to the second and third contact 204, 206, respectively, generate inductive crosstalk. In this embodiment, the first contact 202 is coupled via the capacitive coupler 216 to the second contact 204 and the third contact 206 in parallel. In this embodiment, the capacitive coupler 216 is capacitively coupled to the first contact 202 and conductively coupled to each of the second contact 204 and the third contact 206. In other words, capacitive crosstalk is introduced to the first contact 202 from each of the second and third contacts 204, 206, respectively. As illustrated in FIG. 5, the first contact 202 is coupled via the capacitive coupler 216 including the conductive plate 218 at the first contact 202 to the second contact 204. The first contact 202 is also coupled to the third contact 206 via the capacitive coupler 216 including the conductive plate 220 at the first contact 202

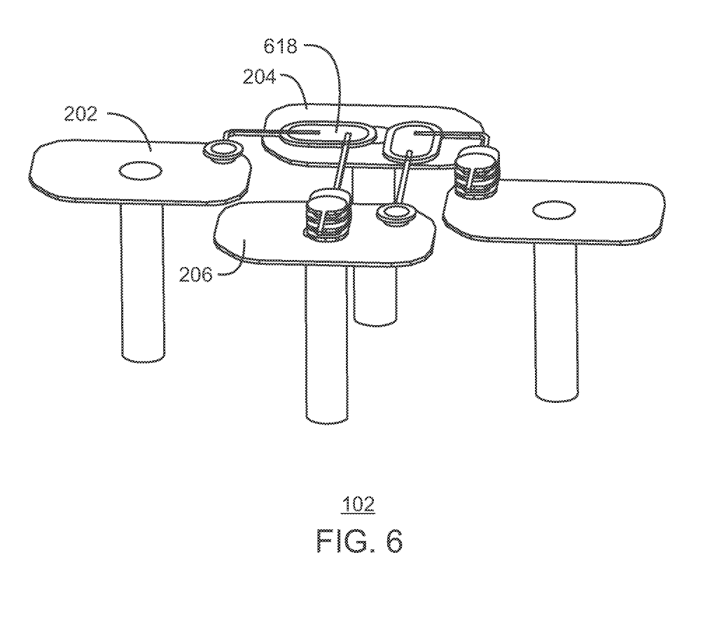

FIG. 6 is a diagram showing the capacitive coupler 216 including a relatively larger conductive plate 618. The degree to which the capacitive coupler 216 can reduce or cancel inductive crosstalk may depend on the size of the conductive plate 618 or distance between the conductive plate 618 and the second contact 204. As illustrated in FIG. 6, the size of the conductive plate 618 is relatively large in comparison to the conductive plate 218 shown in FIGS. 2-5. In this embodiment, the size conductive plate 618 is increased to increase the strength of the introduced capacitive crosstalk.

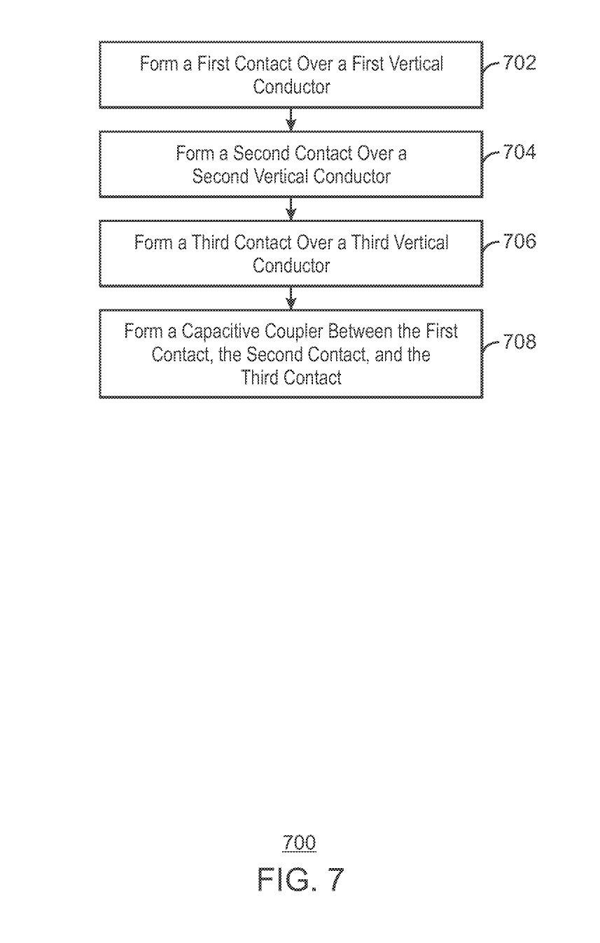

FIG. 7 is a block diagram showing a method 700 of manufacturing a printed circuit board to reduce crosstalk between contacts. At block 702, a first contact is formed over a first vertical conductor. At block 704, a second contact is formed over a second vertical conductor. The method 700 includes forming, at block 706, a third contact over a third vertical conductor. The method 700 includes forming, at block 708, a capacitive coupler between the first contact, the second contact, and the third contact, wherein the capacitive coupler is to cancel inductive crosstalk received at the second vertical conductor and third vertical conductor from the first vertical conductor.

The crosstalk can be inductive crosstalk generated at the first vertical conductor and received at the second vertical conductor and the third vertical conductor. The inductive crosstalk can be reduced or cancelled by the capacitive coupling. In some embodiments, the capacitive coupling is a sequential coupling. In this embodiment, the method 700 includes forming a capacitive coupling from the first contact to the second contact, and forming a capacitive coupling from the second contact to the third contact. In some embodiments, the capacitive coupling is a parallel coupling. For example, the method 700 can include forming a capacitive coupling from the first contact to the second contact; and forming a capacitive coupling from the first contact to the third contact.

In some embodiments, at block 708, forming the capacitive coupling comprises forming a conductive plate disposed above the second contact to form a parallel-plate capacitor with the second contact. In other embodiments, forming, at block 708, the capacitive coupling comprises forming a conductive plate disposed above the third contact to form a parallel-plate capacitor with the third contact.

In some embodiments, the degree to which the capacitive coupling reduces or cancels inductive crosstalk depends on the size of the conductive plates of the capacitive coupling. In this embodiment, the method 700 includes forming a conductive plate of the capacitive coupler, wherein the reduction of the crosstalk depends on the size of the conductive plate.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the present techniques. The various appearances of “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is to be understood that specifics in the aforementioned examples may be used anywhere in one or more embodiments. For instance, all optional features of the computing device described above may also be implemented with respect to either of the methods or the computer-readable medium described herein. Furthermore, although flow diagrams and/or state diagrams may have been used herein to describe embodiments, the techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. An apparatus, comprising:
a first contact coupled to a first vertical conductor;
a second contact coupled to a second vertical conductor;
a third contact coupled to a third vertical conductor; and
a capacitive coupler capacitively coupling the first contact to the second and third contact, wherein the capacitive coupler is to cancel inductive crosstalk received by the second and third vertical conductors

2. The apparatus of claim 1, wherein the capacitive coupler comprises a conductive plate, and wherein the reduction of the crosstalk depends on the size of the conductive plate.

3. The apparatus of claim 1, wherein the capacitive coupler between the first contact and the second and third contact is a sequential coupling from the first contact to the second contact and from the second contact to the third contact.

4. The apparatus of claim 1, wherein the capacitive coupler between the first contact and the second and third contact is a parallel coupling from the second contact to the first contact and from the third contact to the first contact.

5. The apparatus of claim 1, wherein the inductive crosstalk is generated at one of the vertical conductors, is received at another vertical conductor, and is cancelled by introducing capacitive crosstalk via the capacitive coupler.

6. The apparatus of claim 1, wherein the capacitive coupler comprises a conductive plate disposed above the second contact to form a parallel-plate capacitor with the second contact.

7. The apparatus of claim 1, wherein the capacitive coupler comprises a conductive plate disposed above the third contact to form a parallel-plate capacitor with the third contact.

8. The apparatus of claim 1, wherein the capacitive coupler is conductively coupled to the first contact, and capacitively coupled to each of the second contact and the third contact.

9. The apparatus of claim 1, wherein the capacitive coupler is conductively coupled to each of the second contact and the third contact, and capacitively coupled to the first contact.

10. A printed circuit board, comprising:
a first contact;
a second contact;
a third contact; and
a coupler between the first contact, the second contact, and the third contact to reduce inductive crosstalk by introducing capacitive crosstalk.

11. The printed circuit board of claim 10, comprising:
a first vertical conductor communicatively coupled to the first contact and extending into the printed circuit board; and
a second vertical conductor communicatively coupled to the second contact and extending into the printed circuit board; and
a third vertical conductor communicatively coupled to the third contact and extending into the printed circuit board, wherein any of the first vertical conductor, the second vertical conductor, and the third vertical conductor generates the inductive crosstalk.

11. The printed circuit board of claim 9, wherein the coupler is a capacitive coupler comprising a conductive plate disposed above the second contact to form a parallel-plate capacitor with the second contact.

12. The printed circuit board of claim 9, wherein the coupler is a capacitive coupler comprising a conductive plate disposed above the third contact to form a parallel-plate capacitor with the third contact.

13. The printed circuit board of claim 9, wherein the coupler comprises a conductive plate, and wherein the reduction of the crosstalk depends on the size of the conductive plate.

14. The printed circuit board of claim 9, wherein the coupler between the first contact and the second and third contact is a sequential coupler from the first contact to the second contact and from the second contact to the third contact.

15. The printed circuit board of claim 9, wherein the coupler between the first contact and the second and third contact is a parallel coupling from the second contact to the first contact and from the third contact to the first contact.

16. The printed circuit board of claim 9, wherein the coupler is a capacitive coupler comprising a conductive plate disposed above the first contact to form a parallel-plate capacitor with the first contact.

17. A method, comprising:
forming a first contact over a first vertical conductor;
forming a second contact over a second vertical conductor;
forming a third contact over a third vertical conductor; and
forming a capacitive coupler between the first contact, the second contact, and the third contact, wherein the capacitive coupler is to cancel inductive crosstalk received by the first vertical conductor, the second vertical conductor, or the third vertical conductor.

18. The method of claim 17, comprising forming a conductive plate of the capacitive coupler, wherein the reduction of the crosstalk depends on the size of the conductive plate.

19. The method of claim 17, wherein forming the capacitive coupling between the first contact and the second and third contact comprises:
forming a capacitive coupling from the first contact to the second contact; and
forming a capacitive coupling from the second contact to the third contact.

20. The method of claim 17, wherein forming the capacitive coupling between the first contact and the second and third contact comprises:
forming a capacitive coupling from the first contact to the second contact; and
forming a capacitive coupling from the first contact to the third contact.

21. The method of claim 17, wherein forming the capacitive coupling comprises forming a conductive plate disposed above the second contact to form a parallel-plate capacitor with the second contact.

22. The method of claim 17, wherein forming the capacitive coupling comprises forming a conductive plate disposed above the third contact to form a parallel-plate capacitor with the third contact.

23. The method of claim 17, wherein forming the capacitive coupling comprises forming a conductive plate disposed above the first contact to form a parallel-plate capacitor with the first contact.
